(19) United States
(12) Patent Application Publication
(10) Pub. No.: US 2026/0017440 A1
(43) Pub. Date: Jan. 15, 2026

(54) APPARATUS AND METHOD FOR ESTIMATING CONTAMINATION SOURCE LOCATION WITHIN A DESIGNATED SPACE

(71) Applicants: Samsung Electronics Co., Ltd., Suwon-si (KR); Seoul National University R&DB Foundation, Seoul (KR)

(72) Inventors: Jaehee Chang, Suwon-si (KR); Haecheon Choi, Seoul (KR); Sehyeong Oh, Suwon-si (KR); Changbeom Kim, Seoul (KR); Hyun Chul Lee, Suwon-si (KR); Joonseon Jeong, Suwon-si (KR)

(21) Appl. No.: 19/264,731

(22) Filed: Jul. 9, 2025

(30) Foreign Application Priority Data
Jul. 9, 2024 (KR) 10-2024-0090666

(51) Int. Cl. G06F 30/28; G06F 30/27

(52) U.S. Cl. CPC G06F 30/28; G06F 30/27

(57) ABSTRACT

An apparatus for estimating a location of a contamination source in a designated space includes a processor, and a memory operatively connected to the processor and storing instructions that, when executed by the processor, cause the apparatus to measure a concentration of a contaminant diffusing from the contamination source within the designated space by using at least one sensor and estimate the location of the contamination source based on the measured concentration, where the instructions cause the processor to estimate the location of the contamination source by using a neural network trained to output the location of the contamination source when the measured concentration is input.

### CROSS-REFERENCE TO RELATED APPLICATION

This application claims priority to Korean Patent Application No. 10-2024-0090666, filed on Jul. 9, 2024, and all the benefits accruing therefrom under 35 U.S.C. § 119, the content of which in its entirety is herein incorporated by reference.

### BACKGROUND

### 1. Field

The disclosure relates to an apparatus and method for estimating a contamination source location within a designated space.

### 2. Description of the Related Art

If the quality of products manufactured in a designated space is directly affected by an environment of the designated space, the cleanliness of the air in the designated space needs to be maintained at a certain level or higher. For example, in a clean room for manufacturing semiconductor devices, integrated circuits, precision machines, etc., various micro-processes using chemical substances are performed, and thus, cleanliness management of the clean room is necessary to maintain the quality of manufactured products.

In particular, if a contamination source including volatile or fine contamination-causing substances is exposed to the air in a designated space, the contamination-causing substances may be spread from the contamination source into the space according to airflow in the space. Accordingly, even if a small amount of contaminant is exposed to the air for a short period of time, the damage to the manufacturing quality may be much greater.

Therefore, a technology for accurately estimating the location of a contamination source and taking immediate measures against the contaminant is required.

### SUMMARY

Provided are an apparatus and a method for estimating a contamination source location within a designated space. The technical problems to be solved are not limited to the problems mentioned above, and other problems not mentioned will be clearly understood from the following embodiments.

Additional aspects will be set forth in part in the description which follows and, in part, will be apparent from the description, or may be trained by practice of the presented embodiments of the disclosure.

According to an aspect of the disclosure, an apparatus for estimating a location of a contamination source in a designated space includes: a processor and a memory operatively connected to the processor and storing instructions that, when executed by the processor, cause the apparatus to measure a concentration of a contaminant diffusing from the contamination source within the designated space by using at least one sensor and estimate the location of the contamination source based on the measured concentration, where the instructions cause the processor to estimate the location of the contamination source by using a neural network trained to output the location of the contamination source when the measured concentration is input.

According to another aspect of the disclosure, a method of estimating a location of a contamination source in a designated space includes measuring a concentration of a contaminant diffusing from the contamination source within the designated space by using at least one sensor and estimating the location of the contamination source based on the measured concentration, where the estimating of the location of the contamination source includes estimating the location of the contamination source by using a neural network trained to output a location of the contamination source when the measured concentration is input.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram showing an apparatus for estimating a contamination source location in a designated space, according to an embodiment;

FIG. 2 is a diagram for explaining the estimation of a contamination source location by using a neural network, according to an embodiment;

FIG. 3 is a diagram showing a neural network that the apparatus trains to estimate a contamination source location;

FIG. 4 is a diagram for explaining a process of generating a training data set for training the neural network of FIG. 3;

FIG. 5A is a diagram showing an actual contamination source location and a sensor location in a three-dimensional coordinate system, according to an embodiment;

FIG. 5B is a diagram showing a spatial concentration distribution corresponding to an actual contamination source location and a sensor location of FIG. 5A;

FIG. 6A is a diagram showing an instantaneous velocity field of a fluid in a clean room of FIG. 5A;

FIG. 6B is a diagram showing an average velocity field of a fluid in the clean room of FIG. 5A;

FIG. 7A is a graph showing contamination concentration data corresponding to the location of the sensor of FIG. 5A based on the instantaneous velocity field of FIG. 6A;

FIG. 7B is pollution concentration data corresponding to the location of the sensor of FIG. 5A based on the average velocity field of FIG. 6B;

FIG. 8A is a diagram illustrating a spatial concentration distribution based on the pollution concentration data of FIG. 7A;

FIG. 8B is a diagram illustrating a spatial concentration distribution based on the pollution concentration data of FIG. 7B;

FIG. 9 is a diagram for explaining a process of acquiring pollution concentration data when the operating conditions of a designated space are changed;

FIG. 10 is a flowchart illustrating a method of estimating a contamination source location, according to an embodiment; and

FIG. 11 is a flowchart illustrating a method of training a neural network, according to an embodiment.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminologies used herein are selected from those commonly used by one of ordinary skill in the art in consideration of functions of the current embodiments, and may vary according to the technical intention, precedents, or emergence of new technologies. Also, in particular cases, some terms are arbitrarily selected by the applicant, and in this case, the meanings of these terms will be described in detail in the corresponding parts of the specification. Accordingly, the terms used in the specification should not be simply interpreted based on their names but based on the meaning and content of the whole specification.

It will be further understood that the term “comprises” or “includes” should not be construed as necessarily including various constituent elements and various operations described in the specification, and also should not be construed that portions of the constituent elements or operations of the various constituent elements and various operations may not be included or additional constituent elements and operations may further be included.

It will be understood that, although the terms ‘first’, ‘second’, etc. may be used herein to describe various constituent elements, these constituent elements should not be limited by these terms. These terms are only used to distinguish one constituent element from another.

The descriptions of the embodiments should not be interpreted as limiting the scope of right, and embodiments that are readily inferred from the detailed descriptions and embodiments by those of ordinary skill in the art will be construed as being included in the inventive concept. Reference will now be made in detail to embodiments, examples of which are illustrated in the accompanying drawings.

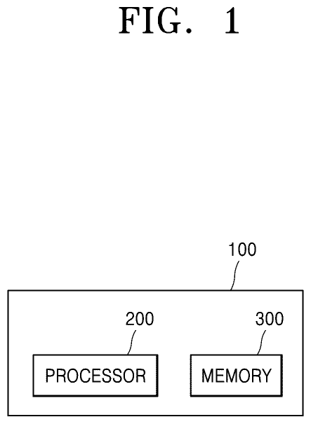

FIG. 1 is a block diagram showing an apparatus 100 for estimating a contamination source location in a designated space according to an embodiment. Referring to FIG. 1, the apparatus 100 for estimating a contamination source location in a designated space according to an embodiment may include a processor 200 and a memory 300. However, only components related to the embodiments are illustrated in the apparatus 100 illustrated in FIG. 1, and it is obvious to those skilled in the art that other components may also be included in the apparatus 100 in addition to the components illustrated in FIG. 1.

The designated space may be an indoor space designed to control the concentration of airborne particles within a certain range. For example, the designated space may be a clean room of a fabrication facility (“FAB”). That is, the designated space may be a clean space equipped with internal equipment for manufacturing semiconductors.

However, the products manufactured in the designated space are not limited to semiconductors, and if the products undergo a manufacturing process in which the manufacturing quality may be directly affected by the environment of the designated space, they may be applied without limitation. For another example, the designated space may be a clean space equipped with internal equipment for manufacturing displays.

Because the semiconductor manufacturing process is a micro-process using multiple chemical substances, it may be important to control the environment of the designated space to ensure the manufacturing quality of semiconductors. For example, if air in the designated space is contaminated by a contamination source, it may have an adverse effect on the manufacturing quality of the semiconductor, and accordingly, the defect rate of the produced semiconductor may significantly increase.

In the embodiment, the contamination source may denote a main cause that causes or emits air contamination in the designated space. For example, the contamination source may be any chemical substance leaked during a manufacturing process. For another example, the contamination source may be a foreign substance such as dust, bacteria, or skin cells from the human body. In addition, in the embodiment, a substance that is contaminated by a contaminant and spreads from the contaminant as the fluid moves within the designated space may be referred to as a contaminant.

As the contamination of the air within the designated space continues, the adverse effect on the manufacturing quality of the semiconductor increases, and thus, an environment of the designated space needs to be controlled to quickly dilute or remove the contaminant from the designated space.

However, in the related art, data for estimating the location of a contaminant was obtained by actually measuring an overall concentration distribution of the contaminant within the designated space, actually executing a flow simulation for the fluid within the designated space or collecting complaints from users who actually used the designated space. Because the technologies of the related art take a lot of time to obtain data, there was a problem in that they could not respond quickly when the air within the designated space is contaminated.

Meanwhile, in the past, in order to identify the location of the contaminant, research has also been conducted on apparatuses for monitoring contaminants or methods of arranging sensors for efficiently detecting various types of contaminants. However, the techniques of the related art merely use indirect information about contaminants spread from a contamination source, not direct information about the contamination source, and thus there is a problem that it is difficult to quickly take direct measures against the contamination source.

Accordingly, in the embodiment, an apparatus and a method capable of quickly and directly estimating the location of a contamination source by using a neural network trained to output the location of the contamination source when the concentration of the contaminant measured using a sensor is input are described.

The processor 200 may control an overall operation of various hardware and/or software components provided in the apparatus 100 for estimating the location of the contamination source within a designated space. The processor 200 may be implemented as an arithmetic processor (for example, a Central Processing Unit (“CPU”), a Graphics Processing Unit (“GPU”), a Neural Processing Unit (“NPU”), a Micro Controller Unit (“MCU”), an Application Processor (“AP”), etc.) including a dedicated logic circuit (for example, a Field Programmable Gate Array (“FPGA”), an Application Specific Integrated Circuits (“ASIC”), etc.), but is not limited thereto.

The processor 200 may measure the concentration of a contaminant diffused from a contamination source within a designated space using at least one sensor. The at least one sensor may be placed at an arbitrary location in the designated space separately from the apparatus 100. However, the location of the at least one sensor is not limited thereto, and the at least one sensor may also be placed within the apparatus 100 in another embodiment.

Regardless of the physical location relationship between the apparatus 100 and the at least one sensor, if the apparatus 100 is defined as including components connected thereto, the apparatus 100 may be considered to include at least one sensor, but if the apparatus 100 is defined as including only components placed inside the apparatus 100, the apparatus 100 may be interpreted as not including the at least one sensor.

The processor 200 may estimate the location of the contamination source based on the measured concentration. For example, the processor 200 may estimate the location of the contamination source using a neural network trained to output the location of the contamination source when the measured concentration is input.

The processor 200 may control the environment of a designated space to dilute or remove the contaminant based on the estimated contaminant location. For example, if the designated space is a clean room of a FAB, the processor 200 may control the operation of a fan filter unit (“FFU”) for ventilating the clean room to dilute or remove the contaminant within the clean room.

The memory 300 may store programs and other data for operations performed by the processor 200. The memory 300 may store various data processed within the apparatus 100. For example, the memory 300 may store data processed and data to be processed in the apparatus 100. In addition, the memory 300 may store applications, drivers, etc. to be driven by the apparatus 100.

The memory 300 may include random access memory (“RAM”) such as dynamic random access memory (“DRAM”) and static random access memory (“SRAM”), read-only memory (“ROM”), electrically erasable programmable read-only memory (“EEPROM”), CD-ROM, Blu-ray or other optical disk storage, hard disk drive (“HDD”), solid state drive (“SSD”), or flash memory, and further, may include other external storage devices that may be accessed by the apparatus 100.

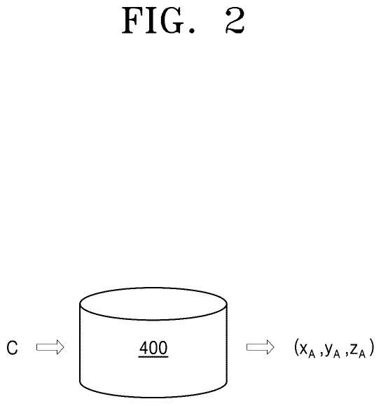

FIG. 2 is a diagram to explain the estimation of a contamination source location using a neural network 400 according to an embodiment. Referring to FIG. 2, the neural network 400 may be a neural network trained to output contamination source locations x_{A}, y_{A}, and z_{A} when a concentration C of a contaminant is input.

The neural network 400 may be an architecture of a deep neural network (“DNN”) or an n-layer neural network. The DNN or the n-layer neural network may correspond to a convolutional neural network (“CNN”), a recurrent neural network (“RNN”), a long short-term memory (“LSTM”), a deep belief network, a restricted Boltzmann machine, a residual neural network (“ResNet”), etc. However, the neural network 400 is not limited thereto, and the neural network 400 may have various architectures.

The concentration C of a contaminant may be a set of concentrations of at least one contaminant measured by at least one sensor at each location. For example, if n sensors (n is a natural number greater than or equal to 1) are placed in a designated space, the location where the j^{th} sensor (j is one of the natural numbers from 1 to n) is placed may be referred to as sⱼ, and the concentration measured by the j^{th} sensor at the location sⱼ may be referred to as cⱼ. That is, the concentration of contaminants measured by n sensors may be collectively referred to as C=(c1, c2, . . . , cn), where the concentration of contaminants C may be data in the form of a 1×n matrix or an n-dimensional vector.

The apparatus 100 may measure the concentration C of contaminant diffused from a contamination source located at an arbitrary contamination source locations x_{A}, y_{A}, and z_{A} using n sensors, and may estimate the contamination source locations x_{A}, y_{A}, and z_{A} by inputting the concentration C of contaminants into the neural network 400. In this case, x_{A}, y_{A}, and z_{A} may denote the coordinates of the contamination source locations in a three-dimensional space composed of an x-axis, a y-axis, and a z-axis.

Because the apparatus 100 according to an embodiment may measure the concentration of a contaminant diffusing from a contamination source within a designated space using at least one sensor and may estimate the location of the contamination source by using the neural network 400 trained to output the location of the contamination source when the concentration of the contaminant is input, and thus, the location of the contamination source may be estimated quickly and directly.

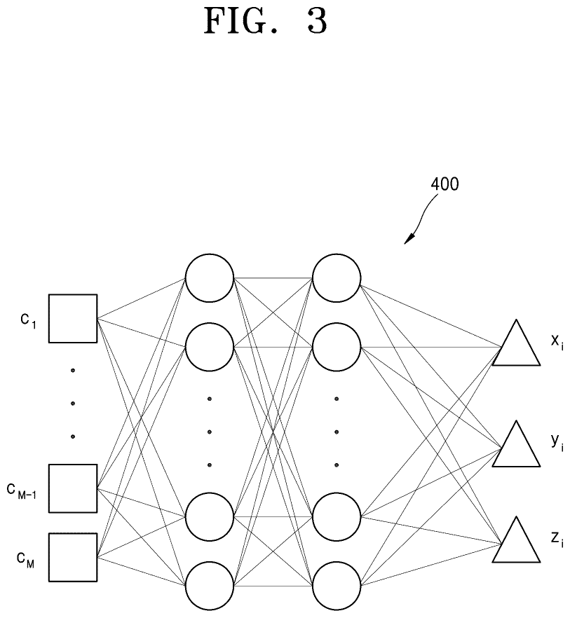

FIG. 3 is a diagram illustrating the neural network 400 that the apparatus 100 trains to estimate the location of the contamination source. Referring to FIG. 3, the apparatus 100 may train the neural network 400 by using data pairs of contamination concentration data c₁, . . . c_{M-1}, and c_{M} and candidate locations xᵢ, yᵢ, and zᵢ of contaminants as a training data set.

In the disclosure, the candidate location of a contamination source may denote a location that is likely to be a location where a contaminant is generated by the contamination source within a designated space, and the contamination concentration data may denote a concentration distribution of the contaminant obtained at a location of at least one sensor corresponding to at least one candidate location of the contamination source.

At least one candidate location of a contaminant may exist within a designated space. For example, if there are N candidate locations of contaminants within a designated space (N is a natural number greater than or equal to 1), the candidate location of the i^{th} contamination source within the designated space (i is one of the natural numbers from 1 to N) may be expressed as a three-dimensional space coordinate such as xᵢ, yᵢ, and zᵢ.

In addition, if M sensors (M is a natural number greater than or equal to 1) are placed within a designated space, the location where the j^{th} sensor (j is one of the natural numbers from 1 to M) is placed may be referred to as sⱼ, and the concentration of the contaminant corresponding to the location sⱼ may be referred to as cⱼ. For example, c_{M-1} of the contamination concentration data c₁, . . . c_{M-1}, c_{M} may be a concentration distribution of a contaminant corresponding to the candidate location xᵢ, yᵢ, and zᵢ of the i^{th} contamination source obtained at a location S_{M-1}.

The neural network 400 may have a structure that outputs a candidate location of the contamination source when the contamination concentration data is input. For example, the neural network 400 may be trained using a data pair (or label data) in which the contamination concentration data and the candidate location of the contamination source are matched. However, the method in which the neural network 400 is trained is not limited thereto, and as another example, the neural network 400 may be trained in a direction in which an output value output as the contamination concentration data is input is the candidate location that is matched with the corresponding contamination concentration data, thereby reducing the error.

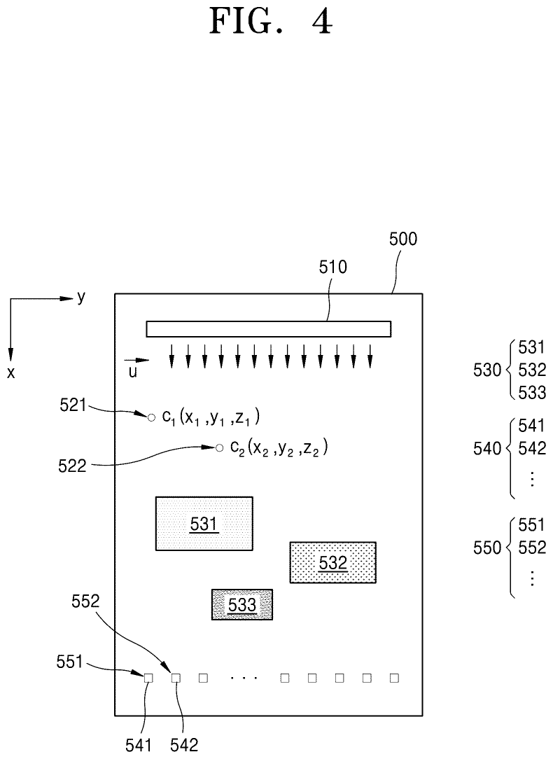

In FIG. 3, although only a neural network in which two layers are fully connected is illustrated, it is not limited thereto. For another example, the number of layers and the connection relationship between nodes included in the layers may be appropriately changed according to the design structure of the neural network. Hereinafter, the process of generating a training data set will be specifically described with reference to FIG. 4.

FIG. 4 is a diagram to explain a process of generating a training data set for training the neural network 400 of FIG. 3. Referring to FIG. 4, a clean room 500 of the FAB may include a fan filter unit 510, at least one internal equipment 530, and at least one sensor 540. However, only components related to the embodiments are illustrated in the clean room 500 illustrated in FIG. 4, and it is obvious to those skilled in the art that other components other than the components illustrated in FIG. 4 may further be included or omitted in the apparatus 100.

The apparatus 100 may acquire contamination concentration data corresponding to a location of at least one sensor by obtaining an average velocity field of a fluid in a designated space through a flow simulation and performing contamination diffusion analysis according to a candidate location of a contamination source using the average velocity field. The apparatus 100 may generate a training data set for training the neural network 400 by changing the candidate location of a contamination source and obtaining contamination concentration data corresponding to the location of at least one sensor. As used herein, the “average velocity field of a fluid” means average velocity distribution of the fluid in the designated space.

The apparatus 100 may obtain an average velocity field of a fluid in the clean room 500 through a flow simulation. For example, the apparatus 100 may obtain an average velocity field of a fluid in the clean room 500 by executing a computational fluid dynamics (“CFD”) simulation using a flow analysis method based on operating conditions of the clean room 500.

The apparatus 100 may identify the flow of fluid in the clean room 500 according to the operating conditions of the clean room 500 through computational fluid dynamics simulation. The fan filter unit 510 may continuously provide clean air flowing in one direction to the clean room 500. For example, the fan filter unit 510 may continuously provide clean air flowing in a direction from the top to the bottom of the clean room 500 (e.g., +y-axis direction). As clean air is provided to the clean room 500, fluid movement in the clean room 500 may be induced, and the movement of the fluid may be affected by the operating conditions in the clean room 500.

The operating conditions of the clean room 500 may include a size of the clean room 500, a shape of the clean room 500, a wind speed of the clean room 500, an arrangement structure of at least one internal equipment 530 placed in the clean room 500, the arrangement structure of the fan filter unit 510, and/or the arrangement structure of at least one sensor 540 (e.g., 541, 542 . . . ). The at least one internal equipment 530 may include all types of facilities necessary for manufacturing semiconductors. However, it is not limited to the equipment directly required for the manufacture of semiconductors, and at least one internal equipment 530 may also include equipment indirectly used for the manufacture of semiconductors in another embodiment.

If any of the operating conditions of the clean room 500 changes, the flow of fluid in the clean room 500 that apparatus 100 identifies through a CFD simulation may change. For example, even if clean air with the same wind speed is provided to the clean room 500 by the fan filter unit 510, if the positions of a first internal equipment 531 and a second internal equipment 532 are changed, the flow of fluid in the clean room 500 that the apparatus 100 identifies through computational fluid dynamics simulation may change.

The apparatus 100 may use various flow analysis methods to obtain an average velocity field of the fluid in the clean room 500 through a flow simulation. The flow analysis method may include at least one of direct numerical simulation method, a large-eddy simulation (“LES”) method, a Reynolds-averaged Navier-Stokes simulation (“RANS”) method, a hybrid LES-RANS method, and a wall-modelled large-eddy simulation (“WMLES”) method. However, the flow analysis method is not limited thereto and may be applied without limitation as long as it is a flow analysis method that may obtain an average velocity field of a fluid in the clean room 500 through the flow simulation.

The apparatus 100 may perform contamination diffusion analysis according to the candidate location of the contamination source using the average velocity field obtained as a result of the flow simulation. For example, the apparatus 100 may perform the contamination diffusion analysis using the average velocity field and a one-way coupled transport equation for the contamination source such as the Mathematical Equation 1 below.

$$\frac{\partial c}{\partial t} + \overline{u} \cdot ∇ c - \frac{1}{{P}_{e}} {∇}^{2} c = {c}_{s} ( {x}_{i} , {y}_{i} , {z}_{i} ) , \qquad [ Mathematical Equation 1 ]$$

In this case, c indicates the concentration distribution of contaminants in the clean room 500, ū indicates the average velocity field obtained as a result of the flow simulation, Pe indicates the Peclet number, and cₛ(xᵢ, yᵢ, zᵢ) denotes the amount of contaminants (e.g., unit: milligram (mg)) generated per second from a contamination source when the candidate location of the contamination source is (xᵢ, yᵢ, zᵢ).

The apparatus 100 may obtain a concentration distribution c of a contaminant that is diffused according to the flow of fluid in the clean room 500 from a contamination source located at a specific candidate location (xᵢ, yᵢ, zᵢ) by performing contamination diffusion analysis. That is, the apparatus 100 may obtain a concentration distribution c of a contaminant in the clean room 500 corresponding to a specific contamination source existing in the candidate location (xᵢ, yᵢ, zᵢ) by performing the contamination diffusion analysis by specifying the candidate location (xᵢ, yᵢ, zᵢ).

For example, the apparatus 100 may obtain a concentration distribution of a contaminant diffused in the clean room 500 from a contamination source, the location of which is designated as the first candidate location 521 or the second candidate location 522 through the one-way transport equation as shown in the following Mathematical Equation 2.

$$\frac{\partial c}{\partial t} + \overline{u} \cdot ∇ c - \frac{1}{{P}_{e}} {∇}^{2} c = {c}_{s} ( {x}_{1} , {y}_{1} , {z}_{1} ) \qquad [ Mathematical Equation 2 ]$$

The apparatus 100 may obtain contamination concentration data c₁, . . . c_{M-1}, c_{M} corresponding to the sensor location 550 (e.g., 551, 552 . . . ) of at least one sensor by performing contamination diffusion analysis while changing the candidate location of the contamination source. That is, the apparatus 100 may generate a training data set for training the neural network 400 by obtaining contamination concentration data c₁, . . . c_{M-1}, c_{M} corresponding to the sensor location 550 of at least one sensor while changing the candidate location of the contamination source.

Although it is described that the apparatus 100 for estimating the location of the contamination source within a designated space performs training of the neural network 400 with reference to FIGS. 2 to 4, it is not necessarily limited thereto. The neural network 400 is trained by a separate device (e.g., a server, etc.) outside the apparatus 100, and the apparatus 100 may receive the trained neural network 400 and perform only inference using the trained neural network 400.

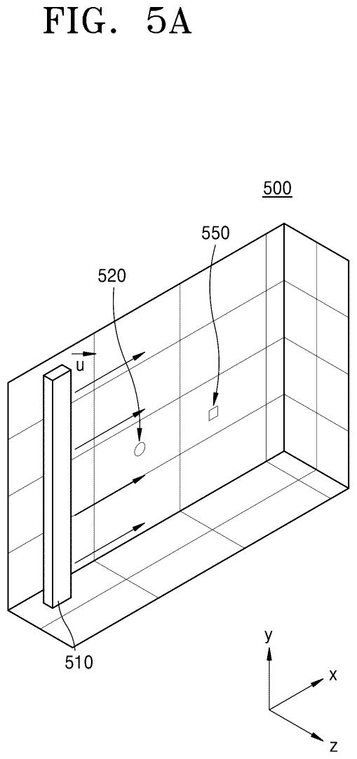

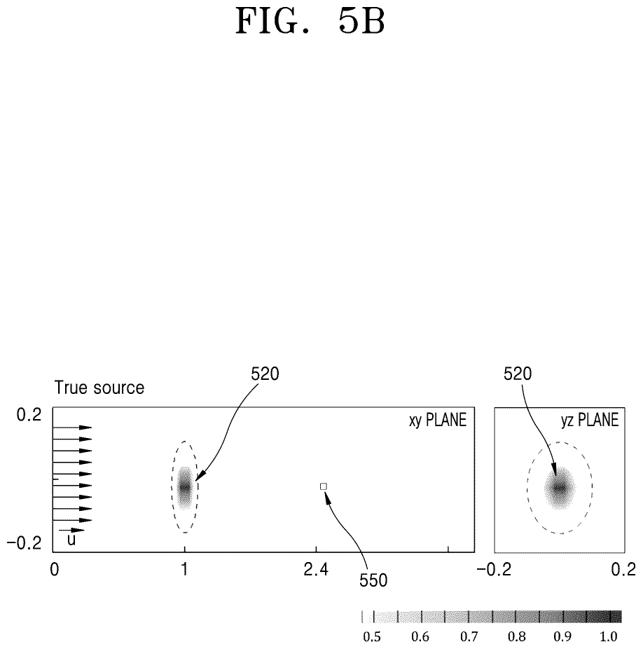

Hereinafter, with reference to FIGS. 5A, 5B, 6A, 6B, 7A, 7B, 8A, and 8B, a case of estimating the location of a contaminant using an average velocity field and a case of estimating the location of a contaminant using an instantaneous velocity field are described by comparison.

FIG. 5A is a drawing showing an actual contamination source location 520 and a sensor location 550 in a three-dimensional coordinate system according to an embodiment. Referring to FIG. 5A, the clean room 500 may include the fan filter unit 510. The components of the clean room 500 illustrated in FIG. 5A may be identical or similar to the components of the clean room 500 of FIG. 4. For example, the clean room 500 of FIG. 5A may include at least one internal equipment 530 and at least one sensor 540, and any duplicate descriptions are omitted below.

The fan filter unit 510 may continuously provide clean air flowing in the +x-axis direction to the clean room 500. Accordingly, contaminants from the contamination source existing at the actual contamination source location 520 may diffuse and reach the sensor location 550.

FIG. 5B is a diagram showing a spatial concentration distribution corresponding to the actual contamination source location 520 and the sensor location 550 of FIG. 5A. In the disclosure, the spatial concentration distribution may represent, in spatial coordinates in a three-dimensional matrix, the concentration of a contaminant diffusing from a contamination source. For example, the spatial concentration distributionϕ of FIG. 5B may represent the concentration of a contaminant diffused from a contamination source at an actual contamination source location 520 in spatial coordinates when the contaminant exists at the actual contamination source location 520.

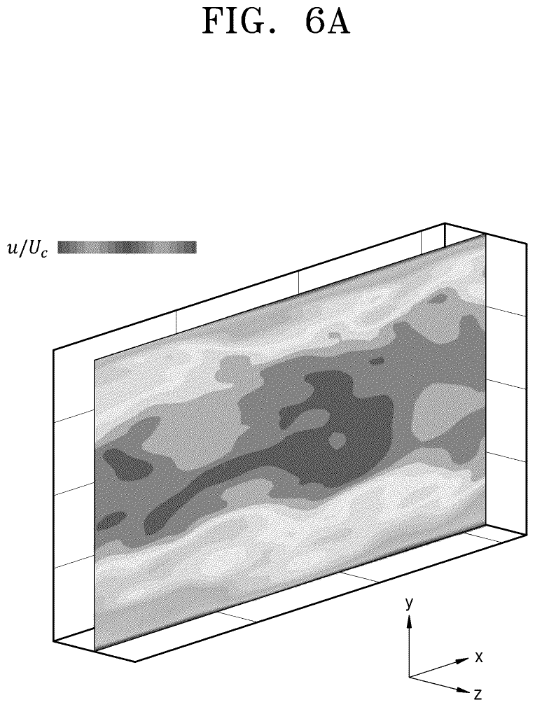

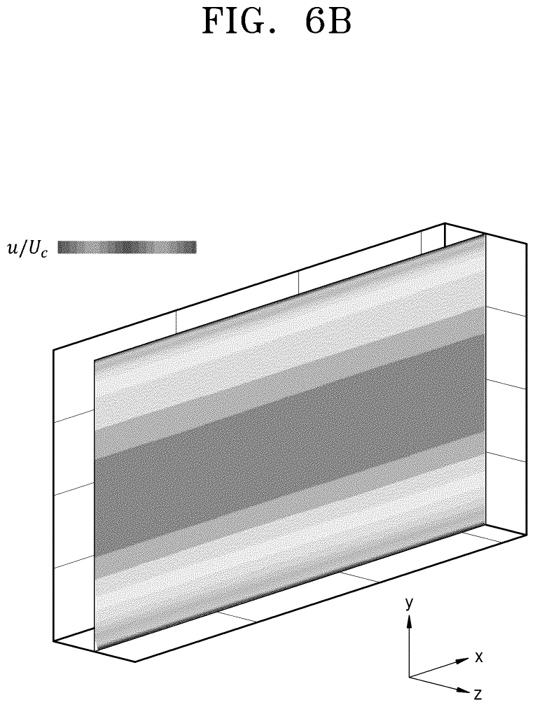

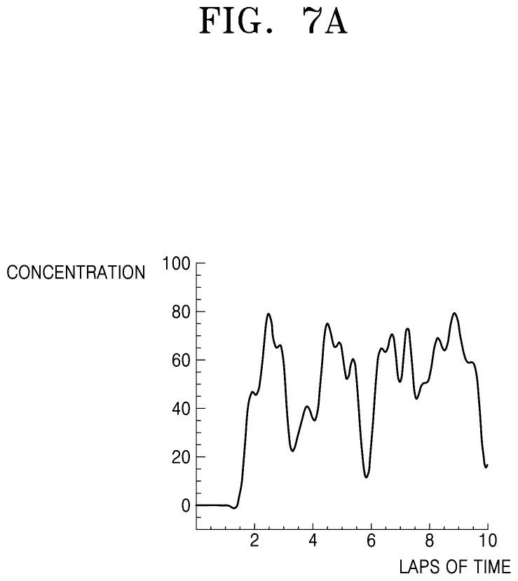

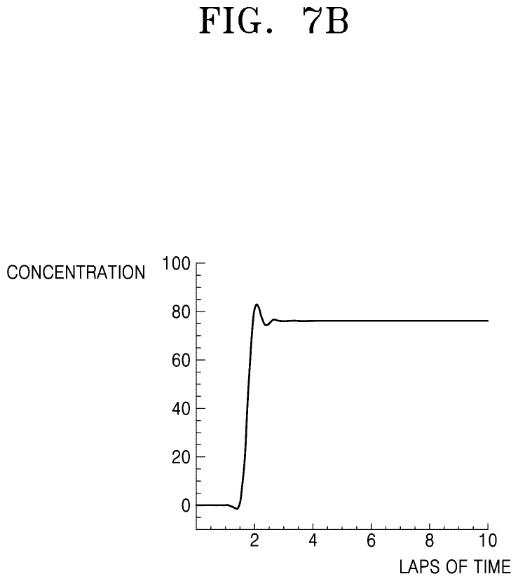

FIG. 6A is a diagram showing an instantaneous velocity field of a fluid in the clean room 500 of FIG. 5A, and FIG. 6B is a diagram showing an average velocity field of a fluid in the clean room 500 of FIG. 5A. FIG. 7A shows contamination concentration data corresponding to the sensor location 550 of FIG. 5A based on the instantaneous velocity field of FIG. 6A, and FIG. 7B is contamination concentration data corresponding to the sensor location 550 of FIG. 5A based on the average velocity field of FIG. 6B. FIGS. 6A and 6B illustrate the ratio of the average velocity (u) to the maximum velocity (U_{c}) of the fluid, represented using shading.

The contamination concentration data of FIG. 7A is a result of plotting the concentration value corresponding to the sensor location 550 of FIG. 5A over time. In this case, the concentration value corresponding to the sensor location 550 may be obtained by performing contamination diffusion analysis on the contamination source existing at the actual contamination source location 520 of FIG. 5A using the instantaneous velocity field of FIG. 6A.

The contamination concentration data of FIG. 7B is a graph plotting the concentration value corresponding to the sensor location 550 of FIG. 5A over time. In this case, the concentration value corresponding to the sensor location 550 may be obtained by performing contamination diffusion analysis on the contamination source existing at the actual contamination source location 520 of FIG. 5A using the average velocity field of FIG. 6B.

Comparing FIG. 7A and FIG. 7B, it may be seen that the contamination concentration data of FIG. 7B is generated as a step function and has a constant value for a certain period of time, whereas the contamination concentration data of FIG. 7A has a value that continuously changes. This is because, when performing contamination diffusion analysis using an instantaneous velocity field, the influence of turbulence is also considered, whereas, when performing contamination diffusion analysis using an average velocity field, the influence of turbulence may be minimized.

In addition, a time taken to obtain the contamination concentration data of FIG. 7B may be shorter than a time taken to obtain the contamination concentration data of FIG. 7A. In the case of the contamination concentration data of FIG. 7A, a process of acquiring an instantaneous velocity field is required each time contamination diffusion analysis is performed, whereas in the case of the contamination concentration data of FIG. 7B, once an average velocity field is acquired, there is no need to acquire the average velocity field again each time contamination diffusion analysis is performed. That is, because there is no need to acquire an average velocity field each time to acquire the contamination concentration data of FIG. 7B, the contamination concentration data of FIG. 7B may be acquired at a faster speed than the contamination concentration data of FIG. 7A.

Because the contamination concentration data of FIG. 7B has a constant value at each interval, there is no need to acquire contamination concentration data for all times and store them in a memory. Accordingly, the time taken to acquire an average velocity field through a flow simulation may be shorter than the time taken to acquire an instantaneous velocity field through a flow simulation, and the contamination diffusion data acquired using an average velocity field may occupy less memory than the contamination concentration data acquired using an instantaneous velocity field.

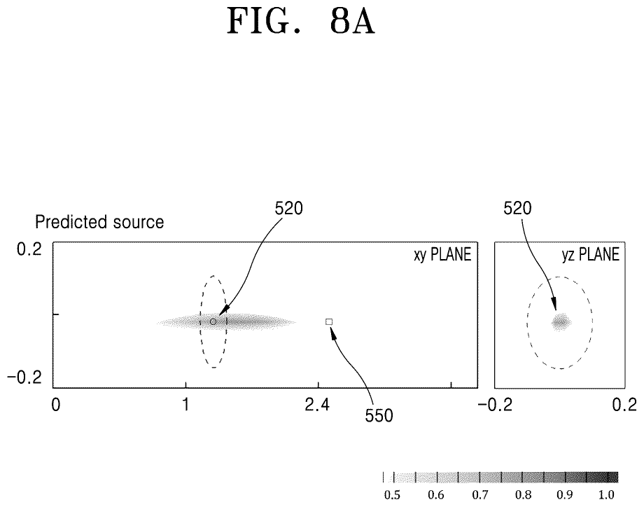

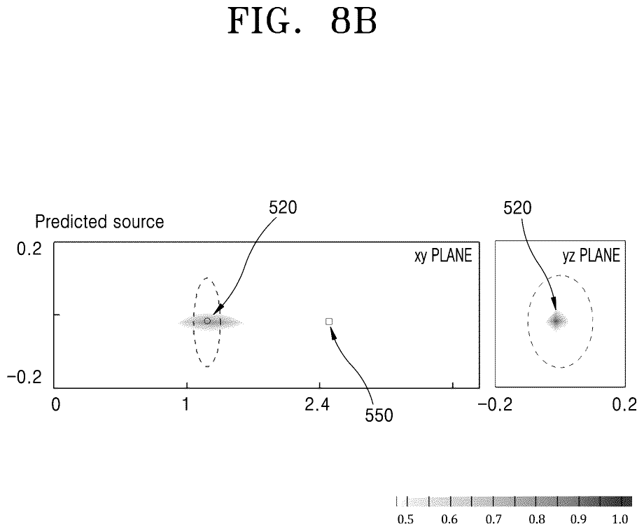

FIG. 8A is a diagram illustrating a spatial concentration distribution based on the contamination concentration data of FIG. 7A, and FIG. 8B is a diagram illustrating a spatial concentration distribution based on the contamination concentration data of FIG. 7B. FIG. 8A is a result of estimating a contamination source location based on the contamination concentration data of FIG. 7A, and FIG. 8B is a result of estimating a contamination source location based on the contamination concentration data of FIG. 7B. FIGS. 8A and 8B depict the probability that a given location corresponds to the contamination source, represented using shading.

Referring to FIGS. 8A and 8B, it may be seen that the estimation result of FIG. 8B is closer to the actual contamination source location 520 of FIGS. 5A and 5B than the estimation result of FIG. 8A. This is because, as explained with reference to FIGS. 7A and 7B, if a contamination diffusion is performed using the average velocity field, it is less affected by turbulence than when a contamination diffusion is performed using the instantaneous velocity field. That is, if a contamination source location based on the results of contamination diffusion analysis is estimated using the average velocity field, the estimation accuracy may further be improved. In addition, as described with reference to FIGS. 7A and 7B, in order to estimate the location of the contamination source based on the results of the contamination diffusion analysis using the instantaneous velocity field, the instantaneous velocity field for all times may be required, but in order to estimate the location of the contamination source based on the results of the contamination diffusion analysis using the average velocity field, only an average velocity field for all times may be required.

Accordingly, a capacity required in the memory to obtain the estimation result of FIG. 8A may be greater than a capacity required in the memory to obtain the estimation result of FIG. 8B. For example, in order to obtain the estimation result of FIG. 8A, an instantaneous velocity field at 1 second, an instantaneous velocity field at 2 seconds . . . , and an instantaneous velocity field at 10 seconds may all be required, but in order to obtain the estimation result of FIG. 8B, only an average velocity field from 1 second to 10 seconds may be required. That is, if the location of the contamination source based on the results of the contamination diffusion analysis is estimated using the instantaneous velocity field, the instantaneous velocity field for all times does not need to be stored in the memory, but only the average velocity field for the entire time needs to be stored in the memory, and thus, the required capacity in the memory may be smaller.

In the case of performing the contamination diffusion analysis using the average velocity field and predicting the location of the contamination source based on the results, because the results of the contamination diffusion analysis have constant values at certain intervals, there is no need to obtain contamination concentration data for all times and store them in the memory 300, and thus, the location of the contamination source may be estimated more quickly.

The apparatus 100 of the disclosure generates a training data set for training the neural network 400 using an average velocity field, and thus, the space of the memory 300 may be saved. The apparatus 100 of the disclosure estimates a location of a contamination source using the neural network 400 that has trained a training data set generated using an average velocity field, and thus, the location of a contamination source may be estimated quickly and accurately.

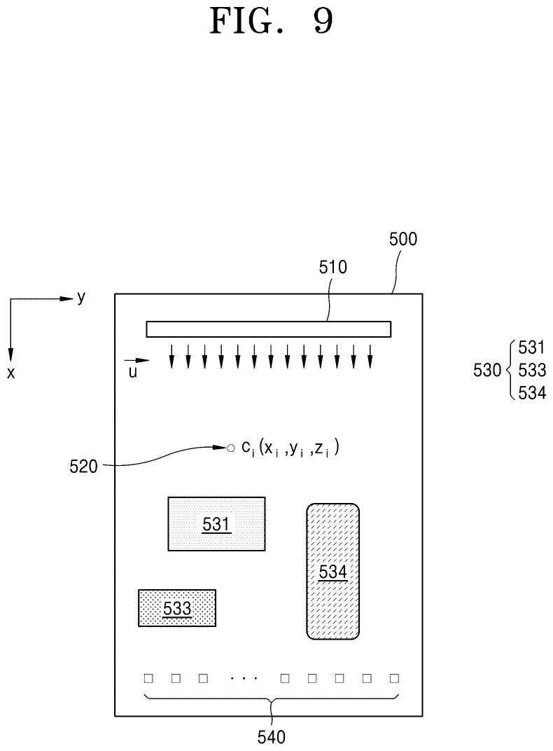

FIG. 9 is a diagram to explain a process of acquiring contamination concentration data when operating conditions of a designated space are changed. Referring to FIG. 9, a clean room 500 may include a fan filter unit 510, at least one internal equipment 530, and at least one sensor 540. The components of the clean room 500 of FIG. 9 may be the same as or similar to the components of the clean room 500 of FIG. 4 except that a fourth internal equipment 534 is included instead of the second internal equipment 532 and the arrangement structure of the third internal equipment 533 is different, and thus, overlapping descriptions are omitted.

If the operating conditions of the clean room 500 are changed, the flow of fluid in the clean room 500 identified by the apparatus 100 through the computational fluid dynamics simulation may change, and thus, the apparatus 100 needs to update the average velocity field based on the changed operating conditions.

If the operating conditions of the clean room 500 are changed, the apparatus 100 may update the average velocity field of the fluid in the clean room 500 by re-executing the computational fluid dynamics simulation using the flow analysis method based on the changed operating conditions. The apparatus 100 may update the contamination concentration data corresponding to the sensor location 550 of at least one sensor by performing contamination diffusion analysis according to the candidate location of the contamination source using the updated average velocity field.

The apparatus 100 of the disclosure may estimate the location of the contamination source more accurately by training the neural network 400 using the updated contamination concentration data or by using the neural network 400 trained using the updated contamination concentration data.

The apparatus 100 may control an operation of the fan filter unit 510 to dilute or remove the contamination source based on the estimated contamination source location. For example, when an actual contamination occurs, the apparatus 100 may increase the wind speed of the fan filter unit 510 or change the wind direction of the fan filter unit 510 so that clean air provided from the fan filter unit 510 is directed toward the location of the contamination source. However, the embodiment is not limited thereto, and for another example, the apparatus 100 may inform the user of the estimated location of the contamination source so that the user may take measures to dilute or remove the contamination source.

Because the apparatus 100 of the disclosure may control the environment of a designated space to dilute or remove the contamination source, damage caused by a contaminant occurring in the designated space may be minimized.

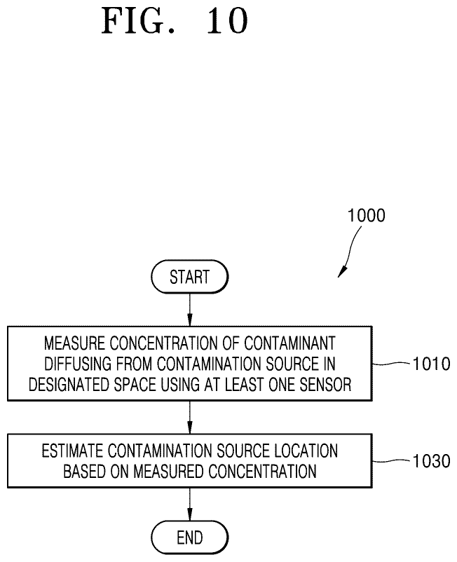

FIG. 10 is a flowchart illustrating a method 1000 of estimating a contamination source location according to an embodiment. Referring to FIG. 10, the method 1000 of estimating a contamination source location in a designated space according to an embodiment may include operations processed in the apparatus 100 for estimating a contamination source location described with reference to FIGS. 1 to 9. Accordingly, the descriptions given above with respect to the apparatus 100 described with reference to FIGS. 1 to 9 may also be applied to the method 1000 of FIG. 10.

In operation 1010, the apparatus 100 may measure the concentration of a contaminant diffusing from a contamination source within a designated space using at least one sensor 540. At least one sensor 540 may be placed at any location in the designated space separate from the apparatus 100, but is not limited thereto, and the at least one sensor 540 may be placed within the apparatus 100 in another embodiment.

In operation 1030, the apparatus 100 may estimate the location of the contamination source based on the measured concentration. The apparatus 100 may estimate the location of the contamination source using a neural network 400 trained to output a location of the contamination source when a measured concentration is input.

The neural network 400 may be a neural network trained to output a location of the contamination source when the concentration of the contamination is input. The neural network 400 may be an architecture of a DNN or an n-layer neural network. The DNN or the n-layer neural network may correspond to a CNN, an RNN, a LSTM, a deep belief network, a restricted Boltzmann machine, Resnet, etc. However, the neural network 400 is not limited thereto and may have various architectures.

The method 1000 of the disclosure may estimate the location of the contaminant by using the neural network 400 that is trained to output the location of a contaminant when the concentration of the contaminant measured is input using at least one sensor 540, and thus, the location of the contaminant may be directly and quickly estimated.

Although not shown, the apparatus 100 may control the environment of a designated space to dilute or remove the contaminant based on the estimated location of the contaminant. For example, if the designated space is a clean room 500 of a FAB, the apparatus 100 may control the operation of the fan filter unit 510 for ventilating the clean room 500 to dilute or remove the contaminant within the clean room 500.

For example, if an actual contamination occurs, the apparatus 100 may increase the wind speed of the fan filter unit 510 or change the wind direction of the fan filter unit 510 so that the clean air provided from the fan filter unit 510 is directed toward the location of the contaminant. However, the embodiment is not limited thereto, and for another example, the apparatus 100 may inform the user of the estimated location of the contamination source so that the user may take measures to dilute or remove the contamination source.

Because the method 1000 of the disclosure may control the environment of the designated space to dilute or remove the contamination source, damage caused by a contaminant occurring in the designated space may be minimized.

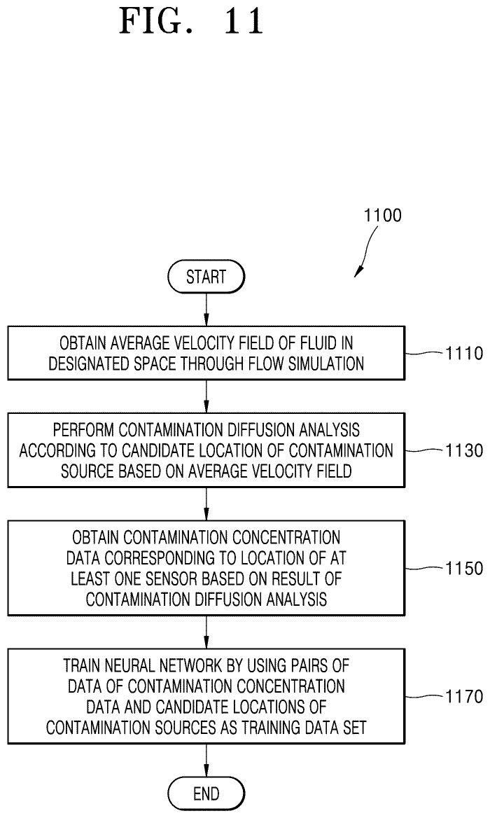

The apparatus 100 may train the neural network 400 by using pairs of data of contamination concentration data and candidate locations of contamination sources as a training data set. Hereinafter, with reference to FIG. 11, a method for the apparatus 100 to train the neural network 400 is described.

FIG. 11 is a flowchart showing a method 1100 for training a neural network 400 according to an embodiment. Referring to FIG. 11, the method 1100 for training the neural network 400 according to an embodiment may include operations processed in the apparatus 100 described with reference to FIGS. 1 to 9. Accordingly, the descriptions given above with respect to the apparatus 100 described with reference to FIGS. 1 to 9 may also be applied to the method 1100 of FIG. 11.

In operation 1110, the apparatus 100 may obtain an average velocity field of a fluid in the clean room 500 through a flow simulation. For example, the apparatus 100 may obtain an average velocity field of the fluid in the clean room 500 by executing a CFD simulation using a flow analysis method based on the operating conditions of the clean room 500.

The apparatus 100 identify the flow of fluid in the clean room 500 according to the operating conditions of the clean room 500 through the CFD simulation. As clean air is supplied to the clean room 500 by the fan filter unit 510, movement of fluid in the clean room 500 may be induced, and the movement of the fluid may be affected by the operating conditions in the clean room 500.

The operating conditions of the clean room 500 may include a size of the clean room 500, a shape of the clean room 500, a wind speed of the clean room 500, the arrangement structure of at least one internal equipment 530 placed in the clean room 500, the arrangement structure of the fan filter unit 510, and/or the arrangement structure of at least one sensor 540. If any one of the operating conditions of the clean room 500 changes, the flow of fluid in the clean room 500 that the apparatus 100) identifies through a CFD simulation may change.

The apparatus 100 may use various flow analysis methods to obtain an average velocity field of the fluid in the clean room 500 through a flow simulation. The flow analysis method may include at least one of a direct numerical simulation method, an LES method, a RANS method, a hybrid LES-RANS method, and a WMLES method. However, the flow analysis method is not limited thereto and may be applied without limitation as long as it is a flow analysis method that may obtain an average velocity field of a fluid in the clean room 500 through the flow simulation.

In operation 1130, the apparatus 100 may perform a contamination diffusion analysis according to the candidate location of the contamination source based on the average velocity field obtained as a result of the flow simulation. For example, the apparatus 100 may perform contamination diffusion analysis by using the average velocity field and the one-way transport equation for the contamination source.

The apparatus 100 may obtain a concentration distribution of a contaminant in the clean room 500 corresponding to a specific contamination source existing in the candidate location by specifying the candidate location of the contamination source and performing the contamination diffusion analysis.

In operation 1150, the apparatus 100 may obtain contamination concentration data corresponding to the sensor location 550 of at least one sensor based on a result of the contamination diffusion analysis obtained by operation 1130. That is, the apparatus 100 may obtain contamination concentration data corresponding to the sensor location 550 of at least one sensor by performing contaminant diffusion analysis while changing the candidate location of the contamination source.

In operation 1170, the apparatus 100 may train the neural network 400 by using the data pairs of the contamination concentration data and the candidate location of the contamination source acquired in operation 1150 as a training data set.

The method 1100 of the disclosure generates a training data set for training the neural network 400 using an average velocity field, and thus, the location of the contamination source may be estimated more quickly and a space of the memory 300 may be saved. The method 1100 of the disclosure estimates the location of the contamination source using the neural network 400 that is trained using the training data set generated using an average velocity field, and thus, the location of the contamination source may be estimated quickly and accurately.

In addition, in order to estimate the contamination source location based on the result of performing contamination diffusion analysis using the average velocity field, the instantaneous velocity field for all times is not required, but only the average velocity field for the entire time is required, and thus, estimating the contamination source location using the average velocity field may require less memory than estimating the contamination source location using the instantaneous velocity field.

In FIGS. 10 and 11, it is described that the apparatus 100 for estimating the contamination source location in a designated space performs training of the neural network 400, but it is not necessarily limited thereto. The neural network 400 is trained by a separate apparatus (e.g., a server, etc.) outside the apparatus 100, and the apparatus 100 may receive the trained neural network 400 and perform only inference using the trained neural network 400.

Although not shown, if the operating conditions of the clean room 500 are changed, the apparatus 100 may re-execute the CFD simulation using a flow analysis method based on the changed operating conditions, and thus, the average velocity field of the fluid within the clean room 500 may be updated.

If the operating conditions of the clean room 500 are changed, the flow of a fluid within the clean room 500 that the apparatus 100 identifies through the CFD simulation may be changed, and therefore, the apparatus 100 needs to update the average velocity field based on the changed operating conditions.

The apparatus 100 may update the pollution concentration data corresponding to the sensor location 550 of at least one sensor by performing contamination diffusion analysis according to the candidate location of the contamination source using the updated average velocity field.

The apparatus 100 of the disclosure may estimate the location of the contamination source more accurately by training the neural network 400 using the updated contamination concentration data or by using the neural network 400 trained using the updated contamination concentration data.

The method 1000 of estimating the location of the contamination source in the designated space described above with reference to FIG. 10 and the method 1100 for training the neural network 400 in FIG. 11 may be recorded on a computer-readable recording medium having one or more programs recorded thereon including commands for executing the method.

Examples of non-transitory computer-readable recording media include magnetic media, such as hard disks, floppy disks, and magnetic tape, optical media, such as CD-ROMs and DVDs, magneto-optical media, such as floptical disks, and hardware devices specifically configured to store and execute program instructions, such as ROM, RAM, flash memory, etc. Examples of program instructions include machine code produced by a compiler as well as high-level language code that may be executed by a computer by using an interpreter, etc.

While the embodiments have been described in detail above, the scope of the disclosure is not limited thereto, and various modifications and improvements made by those skilled in the art using the basic concepts of the disclosure defined in the following claims also fall within the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for estimating a contamination source location in a designated space, the apparatus comprising:
a processor; and
a memory operatively connected to the processor and storing instructions that, when executed by the processor, cause the apparatus to:
measure a concentration of a contaminant diffusing from the contamination source within the designated space by using at least one sensor and
estimate the contamination source location based on the measured concentration,
wherein the instructions cause the processor to estimate the contamination source location by using a neural network trained to output the location of the contamination source when the measured concentration is input.

2. The apparatus of claim 1, wherein the instructions cause the processor to obtain contamination concentration data corresponding to a location of the at least one sensor while changing a candidate location of the contamination source and train the neural network by using data pairs of the candidate location of the contamination source and the contamination concentration data as a training data set.

3. The apparatus of claim 2, wherein the instructions cause the processor to obtain an average velocity field of a fluid within the designated space through a flow simulation, perform contamination diffusion analysis according to the candidate location of the contamination source based on the average velocity field, and obtain the contamination concentration data corresponding to the location of the at least one sensor based on a result of the contamination diffusion analysis.

4. The apparatus of claim 3, wherein the flow simulation includes executing a computational fluid dynamics (CFD) simulation by using a flow analysis method based on operating conditions of the designated space.

5. The apparatus of claim 4, wherein the operating conditions of the designated space include at least one of a size of the designated space, a shape of the designated space, a wind speed of the designated space, and an arrangement structure of at least one internal equipment arranged in the designated space.

6. The apparatus of claim 4, wherein the flow analysis method includes at least one of a direct numerical simulation method, a large-eddy simulation (LES) method, a Reynolds-averaged Navier-Stokes simulation (RANS) method, a hybrid LES-RANS method, and a wall-modelled large-eddy simulation (WMLS) method.

7. The apparatus of claim 4, wherein when the operating conditions change, the instructions cause the processor to update the average velocity field based on the changed operating conditions, and
update the contamination concentration data based on the updated average velocity field.

8. The apparatus of claim 3, wherein the instructions cause the processor to perform the contamination diffusion analysis by using the average velocity field and following one-way coupled transport equation for the contamination source:
$$\frac{\partial c}{\partial t} + \overline{u} \cdot ∇ c - \frac{1}{{P}_{e}} {∇}^{2} c = {c}_{s} ( {x}_{i} , {y}_{i} , {z}_{i} ) ,$$
where c indicates concentration distribution of the contaminant in the designated space, ū indicates the average velocity field obtained as a result of the flow simulation, Pe indicates Peclet number, and cₛ(xᵢ, yᵢ, zᵢ) denotes amount of contaminant generated per second from the contamination source when the candidate location of the contamination source is (xᵢ, yᵢ, zᵢ).

9. The apparatus of claim 5, wherein the designated space is a clean room of a fabrication facility (FAB), and
the at least one internal equipment includes a fan filter unit (FFU) for ventilating the clean room.

10. The apparatus of claim 9, wherein the instructions cause the processor to control operation of the FFU to dilute or remove the contaminant within the clean room based on the estimated contamination source location.

11. A method of estimating a contamination source location in a designated space, the method comprising:
measuring a concentration of a contaminant diffusing from the contamination source within the designated space by using at least one sensor; and
estimating the contamination source location based on the measured concentration,
wherein the estimating of the location of the contamination source comprises estimating the contamination source location by using a neural network trained to output a location of the contamination source when the measured concentration is input.

12. The method of claim 11, further comprising:
training the neural network,
wherein the training of the neural network comprises:
obtaining contamination concentration data corresponding to the location of the at least one sensor while changing a candidate location of the contamination source; and
training the neural network by using data pairs of the candidate location of the contamination source and the contamination concentration data as a training data set.

13. The method of claim 12, wherein the obtaining of the contamination concentration data comprises:
obtaining an average velocity field of a fluid within the designated space through a flow simulation;
performing contamination diffusion analysis according to the candidate location of the contamination source based on the average velocity field; and
obtaining the contamination concentration data corresponding to the location of the at least one sensor based on the result of the contamination diffusion analysis.

14. The method of claim 13, wherein the flow simulation includes executing a CFD simulation by using a flow analysis method based on the operating conditions of the designated space.

15. The method of claim 14, wherein the operating conditions of the designated space include at least one of a size of the designated space, a shape of the designated space, a wind speed of the designated space, and an arrangement structure of at least one internal equipment arranged in the designated space.

16. The method of claim 14, wherein the flow analysis method includes at least one of a direct numerical simulation method, an LES method, an RANS method, a hybrid LES-RANS method, and a WMLS method.

17. The method of claim 14, further comprising:
if the operating conditions are changed, updating the average velocity field based on the changed conditions; and
updating the contamination concentration data based on the updated average velocity field.

18. The method of claim 13, wherein the performing of the contamination diffusion analysis includes performing the contamination diffusion analysis by using the average velocity field and following one-way transport equation for the contamination source:
$$\frac{\partial c}{\partial t} + \overline{u} \cdot ∇ c - \frac{1}{{P}_{e}} {∇}^{2} c = {c}_{s} ( {x}_{i} , {y}_{i} , {z}_{i} ) ,$$
where c indicates concentration distribution of the contaminant in the designated space, ū indicates the average velocity field obtained as a result of the flow simulation, Pe indicates Peclet number, and cₛ(xᵢ, yᵢ, zᵢ) denotes amount of contaminant generated per second from the contamination source when the candidate location of the contamination source is (xᵢ, yᵢ, zᵢ).

19. The method of claim 15, wherein the designated space is a cleanroom of a FAB, and
the at least one internal equipment includes a FFU for ventilating the cleanroom.

20. The method of claim 19, further comprising controlling operation of the FFU to dilute or remove the contaminant within the clean room, based on the estimated contamination source location.
